(19) United States
(12) Patent Application Publication
(10) Pub. No.: US 2010/0014244 A1
(43) Pub. Date: Jan. 21, 2010

(54) THERMAL DEVICE FOR HEAT GENERATING SOURCE

(75) Inventors: LIANG-LIANG CAO, Shenzhen City (CN); YU-HSU LIN, San Jose, CA (US); JENG-DA WU, Tu-Cheng (TW); CHIH-HANG CHAO, Tu-Cheng (TW); YANG LI, Shenzhen City (CN); LEI GUO, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/241,645

(22) Filed: Sep. 30, 2008

(30) Foreign Application Priority Data
Jul. 18, 2008 (CN) 200820301551.1

(51) Int. Cl. H05K 7/20

(52) U.S. Cl. 361/679.48

(57) ABSTRACT

A heat sink for dissipating heat from a heat source, includes a base configured to connect with a heat source, and a plurality of fins positioned on the base. A cutout is defined within the plurality of parallel fins.

### BACKGROUND

1. Technical Field

The present invention relates to a thermal device for dissipating heat from a heat source.

2. Description of Related Art

Developments in the computers are continuing at a rapid pace. Electronic devices in computers, such as central processing units (CPUs), generate a lot of heat during normal operation, which can deteriorate their operational stability, and damage associated electronic devices. Thus, the heat must be removed quickly to ensure normal operation of the CPU. A typical thermal device includes a typical heat sink mounted on a CPU to remove heat. The typical heat sink includes a plurality of parallel fins and several heat pipes passing through the parallel fins. However, the typical thermal device is usually heavy and the efficiency low.

Therefore, a new thermal device for dissipating heat is desired to overcome the above-described deficiencies.

### BRIEF DESCRIPTION OF THE DRAWINGS

FIG. 1 is an exploded view of an embodiment of a thermal device for dissipating heat.

FIG. 2 is an assembled view of the thermal device of FIG. 1.

### DETAILED DESCRIPTION OF THE EMBODIMENTS

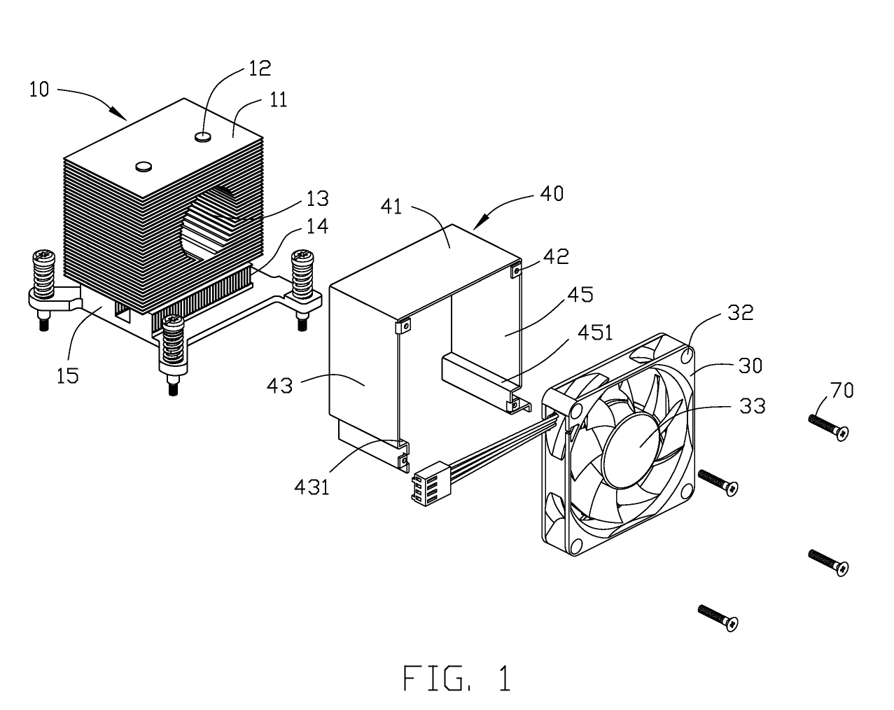

FIG. 1 is an exploded view of an embodiment of a thermal device for dissipating heat from a heat source. The thermal device includes a heat sink 10, a fan 30, and a mounting bracket 40 for fixing the fan 30 onto the heat sink 10.

The heat sink 10 includes a base 15, and a U-shaped heat pipe 12 positioned on a top surface of the base 15. A plurality of parallel fins 11 is positioned on and passing through the heat pipe 12. A cutout 13 is defined within the plurality of parallel fins 11 in a shape similar to the shape of a motor 33 on the fan 30. A bottom surface of the base 15 is configured to connect to a heat source, such as a central processing unit (CPU). The heat generated by the heat source is transmitted from the base 15 to the fins 11 via the heat pipe 12. A plurality of perpendicular conducting fins 14 is positioned on the base 15 to transmit the heat from the bottom surface to the top surface of the base 15.

The mounting bracket 40 is an approximately U-shaped elastic plate. The mounting bracket 40 includes a top wall 41, and two sidewalls 43, 45 extending perpendicularly from opposite edges of the top wall 41 along a same direction. Two support portions 431, 451 protrude toward each other from lower portions of the corresponding sidewalls 43, 45. Four screw holes 42 are defined at corners on one side of the mounting bracket 40. Four fixing holes 32 corresponding to the screw holes 42 are defined at corners of the fan 30.

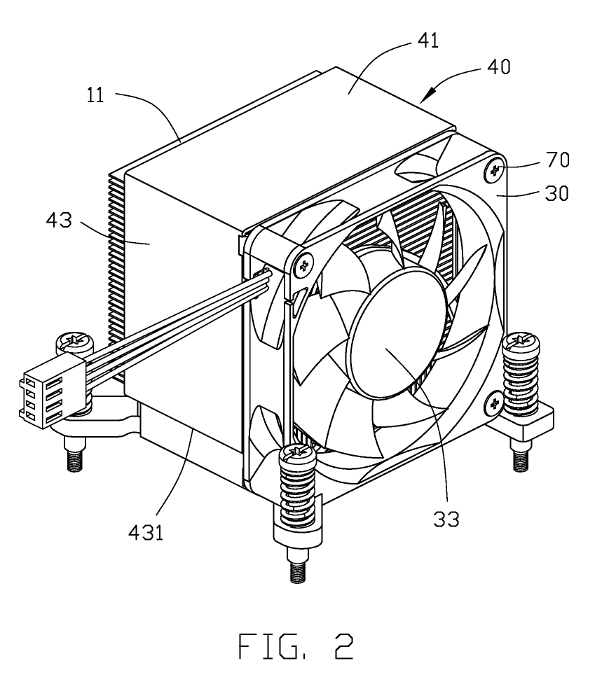

Referring to FIG. 2, in assembly, the sidewalls 43, 45 are pulled outward in opposite directions to receive the parallel fins 11 in a space cooperatively formed by the top wall 41, and the sidewalls 43, 45. When a top fin of the plurality of the parallel fins 11 resists the top wall 41, the sidewalls 43, 45 are released to sandwich the parallel fins 11. The support portions 431, 451 resist a bottom fin of the plurality of parallel fins 11, thereby fixing the mounting bracket 40 to the heat sink 10. The fan 30 is fixed onto the mounting bracket 40 by securing four screws 70 in the screw holes 42 through the fixing holes 32.

The heat generated by the heat source is removed via the parallel fins 11 and airflow produced by the fan 30. Therefore, the cutout 13 will not influence heat dissipation. The heat accumulated around the cutout 13 will be convected away by airflow from the fan 30. The efficiency of heat dissipation is improved and the weight of the heat sink 10 is decreased.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat sink comprising:
a base configured to connect to a heat source; and
a plurality of heat sink fins positioned on the base, wherein a cutout is defined within the plurality of heat sink fins.

2. The heat sink of claim 1, wherein the cutout has a shape similar to a shape of a motor on a fan.

3. The heat sink of claim 2, further comprising at least one heat pipe positioned on the base and passing through the plurality of heat sink fins.

4. The heat sink of claim 3, wherein the plurality of heat sink fins is substantially parallel to a top surface of the base.

5. The heat sink of claim 4, further comprising a plurality of conducting fins positioned on the base.

6. The heat sink of claim 5, wherein the plurality of conducting fins is substantially perpendicular to the top surface of the base.

7. The heat sink of claim 6, further comprising a mounting bracket comprising a top wall, and two sidewalls; a supporting portion is formed at a lower portion of each of the two sidewalls; the top wall resists a top fin of the plurality of heat sink fins and the supporting portions resists a bottom fin of the plurality of heat sink fins to fix the mounting bracket onto the heat sink.

8. The heat sink of claim 7, further comprising a fan mounted onto the mounting bracket.

9. A thermal device comprising:
a fan configured to generate airflow through the thermal device; and
a heat sink mounted on the fan, comprising:
a base configured to connect to a heat source; and
a plurality of heat sink fins positioned on the base, wherein a cutout is defined within the plurality of parallel fins.

10. The heat sink of claim 9, wherein the cutout has a shape similar to a shape of a motor on the fan.

11. The heat sink of claim 10, further comprising at least one heat pipe positioned on the base and passing through the plurality of heat sink fins.

12. The heat sink of claim 11, wherein the plurality of heat sink fins is substantially parallel to a top surface of the base.

13. The heat sink of claim 12, further comprising a plurality of conducting fins positioned on the base.

14. The heat sink of claim 13, wherein the plurality of conducting fins is substantially perpendicular to the top surface of the base.

15. The heat sink of claim 14, further comprising a mounting bracket comprising a top wall, and two sidewalls; a supporting portion is formed at a lower portion of each of the two sidewalls; the top wall resists a top fin of the plurality of heat sink fins and the supporting portions resists a bottom fin of the plurality of heat sink fins to fix the mounting bracket onto the heat sink.
